(19) United States
(12) Patent Application Publication
(10) Pub. No.: US 2025/0042818 A1
(43) Pub. Date: Feb. 6, 2025

(54) METHOD OF MANUFACTURING CERAMIC COMPOSITE WITH CONDUCTIVE OR SUPERCONDUCTING OVER ROOM TEMPERATURE AT ATMOSPHERIC (AMBIENT) PRESSURE AND THE CERAMIC COMPOSITE

(71) Applicant: QUANTUM ENERGY RESEARCH CENTRE (Q-CENTRE), Seoul (KR)

(72) Inventors: Sukbae LEE, Seoul (KR); Kyeong-cheol KIM, Gwangmyeong-si, Gyeonggi-do (KR)

(73) Assignee: QUANTUM ENERGY RESEARCH CENTRE (Q-CENTRE), Seoul (KR)

(21) Appl. No.: 18/593,466

(22) Filed: Mar. 1, 2024

(30) Foreign Application Priority Data
Aug. 1, 2023 (KR) 10-2023-0100619

(51) Int. Cl. C04B 35/447; C04B 35/626; H10N 60/01; H10N 60/85

(52) U.S. Cl. CPC C04B 35/447; C04B 35/6268; H10N 60/01; H10N 60/855; C04B 2235/3296; C04B 2235/407; C04B 2235/42; C04B 2235/726; C04B 2235/767; C04B 2235/96

(57) ABSTRACT

The present invention discloses a method for producing room temperature and atmospheric pressure superconducting ceramic compounds and the ceramic compounds themselves.

The method for producing room temperature and atmospheric pressure superconducting ceramic compounds according to the present invention involves mixing in molar ratios according to Chemical Formula 1, heating and reacting the mixture under vacuum for out gassing, powderizing the reaction product, and conducting secondary heating for vaporization under vacuum.

Pb10-xAx(B(O1-yCy)4)6Dz <Chemical Formula 1>
A: Cu, Ag, Sn, or combinations thereof,
B: P, S, or combinations thereof
C: S and O
D: S, O, e-, or combinations thereof
(x ranges from 0.1 to 7.0, y ranges from 0.001 to 10.0, z ranges from 1 to 4)

Thereby, the effect of exhibiting superconducting properties at room temperature and atmospheric pressure is achieved.

### TECHNICAL FIELD

The present invention relates to a room-temperature and ambient-pressure superconducting ceramic and methods for producing the same. More specifically, the present invention relates to a superconducting ceramic that exhibits superconductivity at room temperature and ambient pressure and methods for producing the superconducting ceramic.

### BACKGROUND ART

Tremendous technological advances have been made in dealing with electrons, to the point where the modem world is called the age of electricity and electronics. The underlying aspect for modem technological advances, of course, lies in sufficient supply of power based on electricity generation, transmission, and distribution. The sufficient supply of power has brought about the development of primary and secondary batteries as power storage media and even wireless power transmission and reception technology and is thus considered a driving force to achieve huge modern developments.

The use of low resistance materials such as copper and gold offers an alternative to solve recently emerging environmental and energy issues and a fundamental solution to the problems (for example, low efficiency) encountered in the high integration/densification of semiconductors. Thus, there is a need to find new materials that can replace low resistance materials while avoiding the problems of the prior art.

Recently, high-temperature superconductors have attracted attention as replacements for low resistance materials. The publication of a new class of superconducting materials with a critical temperature (Tc) above the upper limit of the critical temperature predicted by Bednorz and Muller and the classical BCS theory in 1986 (Bednorz, et al, ZPhys B 64, 189 (1986)) surprised the solid-state physics community.

These materials are ceramics consisting of copper oxide layers separated by buffer cations. In the Bednorz and Muller's original material (LBCO), the buffer cations are lanthanum and barium ions. Their work has inspired Paul Chu to synthesize a similar material containing yttrium and barium ions as buffer ions.

This material is YBCO, the first superconductor with a Tc exceeding the boiling point of liquid nitrogen (77 K) (Wu, et al, Phys Rev Lett 58, 908 (1987)).

According to a report that marked a similar milestone, hydrogen sulfide shows the highest critical temperature of 203.5 K at a pressure of 155 GPa (Conventional superconductivity at 203 kelvin at high pressures in the sulfur hydride system. Nature 525, 73 (2015)).

Even afterwards, related studies have been conducted using similar materials. The critical temperature of recent superconducting materials has been reported to be continuously increasing. For example, a superconducting material reported in 2020 has a critical temperature of 15° C. close to room temperature but requires a very high pressure of 267 GPa. As a result of repeated efforts to lower the required pressure, a material exhibiting superconductivity at about −5° C. and an applied pressure of 186 GPa was reported in 2021. However, the temperature and pressure conditions seem to make it difficult to apply the material to daily life (https://en.Wikipedia.org/wiki/Room-temperature_superconductor).

Despite the fact that the experimental results for the hydrogen sulfide and yttrium superhydride superconducting materials create high expectations for room-temperature superconductors in the academic community, the very high pressures 267 GPa and 186 GPa correspond to approximately 200,000 times higher than the atmospheric pressure (1 atm), making the superconducting materials substantially impossible to apply to industrial fields. Particularly, 267 GPa is converted into more than 2,700 tons applied to an area of 1 cm².

The development of superconducting materials that can be used not only at room temperature but also at ambient pressure is necessary. These materials should not belong to the hydrogen sulfide or yttrium superhydride families, meaning they should not require high pressure, to increase their applicability across various industries, as depicted in FIG. 1.

To achieve room temperature and ambient pressure superconductivity, several considerations must be addressed. According to pages 72-83 of the book “Theoretical Framework of the Superconducting Revolution” (Choi Dong-Sik), published by Korea University Press, it has been reported that one-dimensional characteristics in the electronic structure enhance the feasibility of manufacturing room temperature and ambient pressure superconductors. In 1999, preliminary evidence of materials exhibiting critical temperatures exceeding room temperature was documented in the Pb—Cu—S—P system. X-ray diffraction (XRD) confirmed the structure of compressed lead apatite (Pb₁₀(PO₄)₆O), which contains oxygen.

Subsequently, a patent application was prioritized for the composition modified from Pb₁₀(PO₄)₆O to Pb₁₀₋ₓCuₓ(PO₄)₆O. The elemental composition was confirmed using precise surface component analysis techniques such as X-ray photoelectron spectroscopy (XPS).

The inventors disclosed in their paper and the prior patent application a material containing a small amount of a superconducting substance with a critical temperature exceeding 400K at room temperature and ambient pressure. It was determined that this material, dependent on reaction conditions, is Pb_{6.53}Cu_{3.47}[P(O_{0.82}S_{0.18})₄]_{5.04}(SO₄)_{0.96}O_{0.83}S_{0.17}, rather than the previously mentioned Pb₁₀₋ₓCuₓ(PO₄)₆O. This indicates that the properties of the previously filed material include this composition. Additionally, magnetic properties and conductivity measurements confirmed the inclusion of a superconducting substance.

Subsequent analyses confirmed microwave absorption characteristics, Josephson effects, and thermoelectric properties. These findings suggest the potential for development in areas such as stealth technology, antennas, and quantum devices like quantum computers or quantum sensors within the field of defense science.

### DISCLOSURE OF THE INVENTION

### Problems to be Solved by the Invention

the object of the present invention is to provide a superconducting ceramic and the method that exhibits superconductivity at room temperature and ambient pressure.

### Means for Solving the Problems

The present invention provides a method for producing superconducting ceramic compounds characterized by mixing in molar ratios according to Chemical Formula 1, 1^{st} heating and reacting the mixture under vacuum, out gassing, powderizing the reaction product, and conducting secondary heating for vaporization under vacuum, to solve the first technical challenge described above.

Pb₁₀₋ₓAₓ(B(O_{1-y}C_{y})₄)₆D_{z} <Formula 1>
A: Cu, Ag, Sn, or combinations thereof,
B: P, S, or combinations thereof,
C: S, O,
D: S, O, e⁻, or combinations thereof
(where x is from 0.1 to 7.0, y is from 0.001 to 10.0, and z is from 1 to 4)

According to one embodiment of the present invention, the 1^{st} heating may be carried out at a temperature of 500 to 2000° C.

According to another embodiment of the present invention, the molar ratio may be the stoichiometric coefficient ratio of the reactants in Reaction Scheme 1.

$$\underline{\frac{( 10 - x )}{3} PbO ( s ) + \frac{2 ( 10 - x )}{3} P b {( SO )}_{1} ( s ) + xCu ( s ) + ( \frac{( \text{?} - \text{?} x )}{3} \text{?} ) P ( s ) .} \qquad < Reaction Scheme 1 >$$

$$\underline{{Pb}_{10 - x} {{Cu}_{x} [ ( {P ( {O}_{\text{?}} {S}_{\text{?}} )}_{4} ]}_{( 6 - y )} {{( {SO}_{4} )}_{y} [ {O}_{( 1 - \text{?} )} {S}_{} ]}_{z} + {SO}_{2} ( g ) + \frac{\text{?}}{\text{?}} {S}_{g} ( s )}$$

$$or$$

$$\underline{{Pb}_{10 - x} {{Cu}_{x} [ ( {P ( {O}_{\text{?}} {S}_{\text{?}} )}_{4} ]}_{( 6 - y )} {{( {SO}_{4} )}_{y} [ {O}_{( 1 - \text{?} )} : {2}_{} ]}_{z} + {SO}_{\text{?}} ( g ) + \frac{\text{?}}{\text{?}} {S}_{\text{?}} ( s )}$$

$$\text{?} \text{indicates text missing or illegible when filed}$$

According to another embodiment of the present invention, the outgassing may involve removing a gas containing sulfur oxides.

According to another embodiment of the present invention, the sublimation may involve the sublimation of sulfur.

According to another embodiment of the present invention, the secondary heating may be in the range of 300° C. to 1200° C.

Meanwhile, another technical problem to be solved by the present invention is to disclose a superconducting ceramic compound characterized by being manufactured by the above-described method.

According to another embodiment of the present invention, to achieve room temperature and ambient pressure superconductivity or high conductivity, the material may have an electronic distribution structure that is one-dimensional.

According to another embodiment of the present invention, the material may have an apatite structure among the one-dimensional structures.

According to another embodiment of the present invention, A may be substituted for Pb in the apatite structure of the chemical formula 1 of the present invention.

According to another embodiment of the present invention, in the apatite structure, S may be substituted for P in the phosphate (PO₄³⁻), forming sulfate (SO₄²⁻), or S may be substituted for 0 in the phosphate (PO₄³⁻) forming thiophosphate series (PO₃S²⁻, PO₂S₂²⁻, POS₃²⁻, PS₄²⁻).

According to another embodiment of the present invention, A may be substituted for Pb in the apatite structure of the chemical formula 1, causing the lattice structure to be deformed.

According to another embodiment of the present invention, the ceramic compound may exhibit diamagnetism in response to changes in temperature.

According to another embodiment of the present invention, the ceramic compound may exhibit diamagnetism or ferromagnetism in response to changes in the magnetic field.

According to another embodiment of the present invention, the ceramic compound may exhibit current-voltage characteristics that do not follow Ohm's law (V=IR, where V is voltage, I is current, and R is resistance) with changes in temperature (V*IR).

According to another embodiment of the present invention, the ceramic compound may exhibit current-voltage characteristics that follow V=IR or V*IR in response to changes in the magnetic field.

According to another embodiment of the present invention, the ceramic compound may exhibit resistance-temperature characteristics that follow Ohm's law beyond the transition temperature.

According to another embodiment of the present invention, the four oxygen positions in the one-dimensional channel of the apatite structure of the ceramic compound may be occupied by oxygen (O), sulfur (S), or electride (e⁻).

According to another embodiment of the present invention, the ceramic compound may exhibit a phenomenon where resistance decreases as the amount of current flowing through it increases.

### Effects of the Invention

The superconducting ceramic of the present invention exhibits superconductivity at room temperature and ambient pressure. The methods of the present invention are suitable for producing the superconducting ceramic.

### BRIEF DESCRIPTION OF THE DRAWINGS

FIG. 1 illustrates the applicability of superconductor across various industries.

FIGS. 2 and 3 are schematic diagrams illustrating the structure of the ceramic compound according to the present invention. These figures represent the substitution of A (Cu, Ag, Sn, or combinations thereof) for Pb, the substitution of sulfur for phosphorus in the phosphate, the substitution of sulfur for oxygen in the phosphate, and the filling of the oxygen position in the central part appearing as a 1-Dimension channel with sulfur or electrons. FIG. 2 shows the structure and unit cell of the ceramic compound viewed from the c-axis, which is orthogonal to the a-b plane in a Cartesian coordinate system representing space. FIG. 3 illustrates the unit cell of FIG. 1 along the c-axis perpendicular to the a-b plane, with the solid-line box indicating the unit structure of the ceramic compound of the present invention as an Apatite structure, and the arrow indicating the 1-Dimension channel.

FIG. 4 is a diagram showing the contraction, leading to volume reduction and stress generation, that occurs as copper ions substitute for lead in the Lead-Apatite structure (Pb10(PO4)6O), based on p-XRD calculations.

FIG. 5 is a p-XRD data diagram showing that, during the reaction of the ceramic compound according to the present invention, sulfur is substituted for phosphorus. Depending on the content control of the substitution reaction through phosphorus, the crystal structure becomes more crystalline as Apatite. Even when the molar ratio of phosphorus is less than that of sulfur, leaving about 10% of sulfate ions, the Apatite structure is maintained.

FIG. 6 is a diagram of the XPS measurement results and analysis data, which are experiments conducted to investigate the components of the ceramic compound according to the present invention.

FIG. 7 illustrates the metallic conductivity characteristics and critical current characteristics pattern of the ceramic compound according to the present invention when current is applied.

FIG. 8 is a graph showing the decrease in resistance when the current is continuously increased and applied to the ceramic compound according to the present invention.

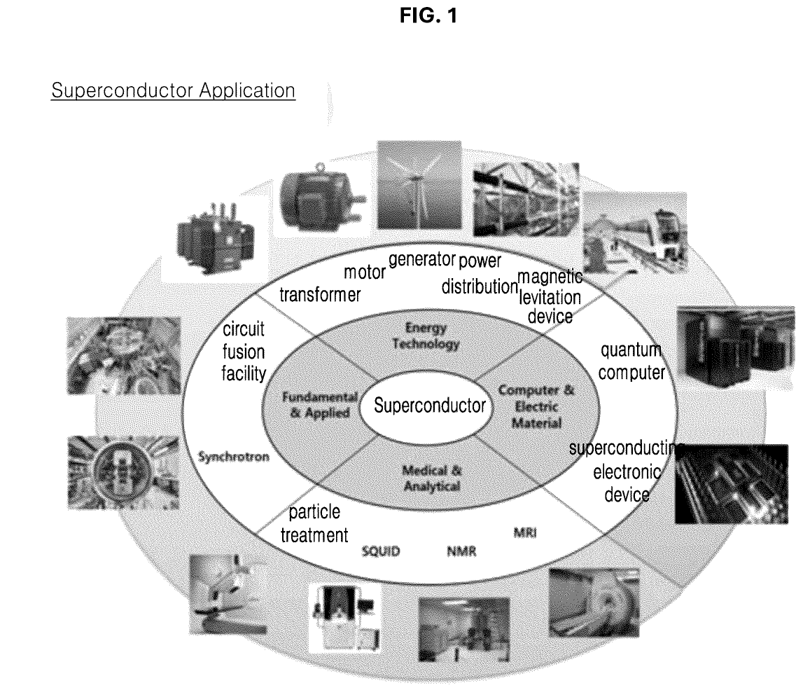

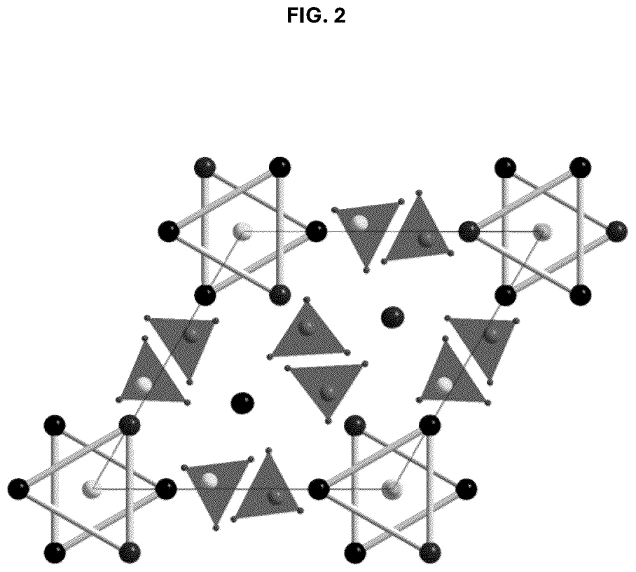

### DETAILED DESCRIPTION FOR CARRYING OUT THE INVENTION

The present invention will now be described in detail.

Technical terms used herein are used to merely illustrate specific embodiments and should be understood that they are not intended to limit the present invention.

As far as not being defined differently, technical terms used herein may have the same meaning as those generally understood by an ordinary person skilled in the art to which the present invention belongs, and should not be construed in an excessively comprehensive meaning or an excessively restricted meaning. If a technical term used herein is an erroneous term that fails to clearly express the idea of the present invention, it should be replaced by a technical term that can be properly understood by the skilled person in the art. In addition, general terms used herein should be construed according to definitions in dictionaries or according to its front or rear context and should not be construed in an excessively restricted meaning. As used herein, the singular forms “a,” “an” and “the” are intended to include the plural forms as well, unless the context clearly indicates otherwise. The terms “comprises”, “comprising”, “includes” and/or “including” as used herein should not be construed to necessarily include all of the elements or steps disclosed herein, and should be construed not to include some of the elements or steps thereof, or should be construed to further include additional elements or steps. In the description of the present invention, detailed explanations of related art are omitted when it is deemed that they may unnecessarily obscure the essence of the invention.

The manufacturing method of the superconducting ceramic compound (LK 99) according to the present invention is characterized by mixing the ceramic compound in the molar ratio according to Chemical Formula 1, adjusting the composition according to Reaction Scheme 1, and then performing a first heating under vacuum to initiate the reaction. This is followed by outgassing, pulverizing the reaction product, and performing a second heating under vacuum to induce sublimation.

Pb₁₀₋ₓAₓ(B(O_{1-y}C_{y})₄)₆D_{z} <Formula 1>
A: Cu, Ag, Sn, or combinations thereof,
B: P, S, or combinations thereof,
C: S, O,
D: S, O, e⁻, or combinations thereof
(where x is from 0.1 to 7.0, y is from 0.001 to 10.0, and z is from 1 to 4)

The ceramic material of Formula 1 and apatite have different physical properties and characteristics despite their structural similarity. The structure of the ceramic material of Formula 1 is herein referred to as “LK99”.

Apatite is a mineral in which metal atoms are bonded to phosphate groups. Apatite has long been commonly used as a dye. Apatite is an electrical insulator with a large energy gap, while LK99 acts as an electrical conductor (particularly a superconductor) because it contains substituents or dopants and defects capable of creating a new energy level.

More specifically, A in Formula 1 is Cu, Sn that has the characteristics of a d-block metal and is an element with d-orbitals as a kind of substituent or dopant and enables conversion from an insulator to a conductor or superconductor.

x in Formula 1 is preferably 0.1 to 7.0. If x is less than 0.1, the structure of the ceramic material may be spatially distorted or negligible intergrain stress may be caused by distortion, failing to form conduction phenomenon. Meanwhile, if x exceeds 7.0, the desired material may not be obtained or an unstable lattice or a different form of lattice may be formed.

According to another embodiment of the present invention, the molar ratio may be the stoichiometric coefficient ratio of the reactants in Reaction Scheme 1.

$$\underline{\frac{( 10 - x )}{3} PbO ( s ) + \frac{2 ( 10 - x )}{3} P b {( SO )}_{1} ( s ) + xCu ( s ) + ( \frac{( \text{?} - \text{?} x )}{3} \text{?} ) P ( s ) .} \qquad < Reaction Scheme 1 >$$

$$\underline{{Pb}_{10 - x} {{Cu}_{x} [ ( {P ( {O}_{\text{?}} {S}_{\text{?}} )}_{4} ]}_{( 6 - y )} {{( {SO}_{4} )}_{y} [ {O}_{( 1 - \text{?} )} {S}_{} ]}_{z} + {SO}_{2} ( g ) + \frac{\text{?}}{\text{?}} {S}_{g} ( s )}$$

$$\underline{or}$$

$$\underline{{Pb}_{10 - x} {{Cu}_{x} [ ( {P ( {O}_{\text{?}} {S}_{\text{?}} )}_{4} ]}_{( 6 - y )} {{( {SO}_{4} )}_{y} [ {O}_{( 1 - \text{?} )} : {2}_{} ]}_{z} + {SO}_{\text{?}} ( g ) + \frac{\text{?}}{\text{?}} {S}_{\text{?}} ( s )}$$

$$\text{?} \text{indicates text missing or illegible when filed}$$

Here, the powders of PbO, Pb(SO)₄, Cu, and P can be prepared and uniformly mixed in the molar ratio of (10-x)/3:2/3(10-x):x:[(8/3(10-x)-y].

Additionally, the reaction mixture is placed in a reaction vessel (e.g., a quartz tube or copper tube), the surrounding environment is evacuated to create a vacuum, and the vessel is sealed.

Next, the reaction vessel is subjected to a first heating at a temperature of 500° C. to 2000° C. to obtain the product, preferably at 770° C. for 12 hours.

If the first heating temperature is below 500° C., adequate mixing may not occur, resulting in insufficient reaction. Conversely, if the temperature exceeds 2000° C., the composition may change due to the high temperature, leading to unintended reactions and composition, as well as energy waste. The heating time should be between 10 and 100 hours; less than 10 hours may result in insufficient reaction, similar to a low temperature, while exceeding 100 hours could lead to excessive energy consumption.

Impurities such as sulfur dioxide (SO₂) may evaporate from the product.

Next, the reaction product is ground into powder, placed into a reaction vessel, vacuum-sealed, and subjected to a second heating at a temperature of 300° C. to 1200° C., preferably at 550° C. for 5 hours.

Here, the second heating temperature may be between 300° C. and 1200° C. If the temperature is below 300° C., the elements may not react sufficiently, making it difficult to form a uniform compound. Conversely, if the temperature exceeds 1200° C., it may be challenging to form the superconducting compound. The heating time should be between 0.001 and 100 hours; if less than 0.001 hours, sufficient reaction and mixing may not occur, while exceeding 100 hours after deposition may result in energy waste.

During the second heating, sublimation occurs, primarily involving the sublimation of substances containing sulfur (S₈(s)).

Through these steps, the ceramic compound (LK-99) according to Chemical Formula 1 can be manufactured.

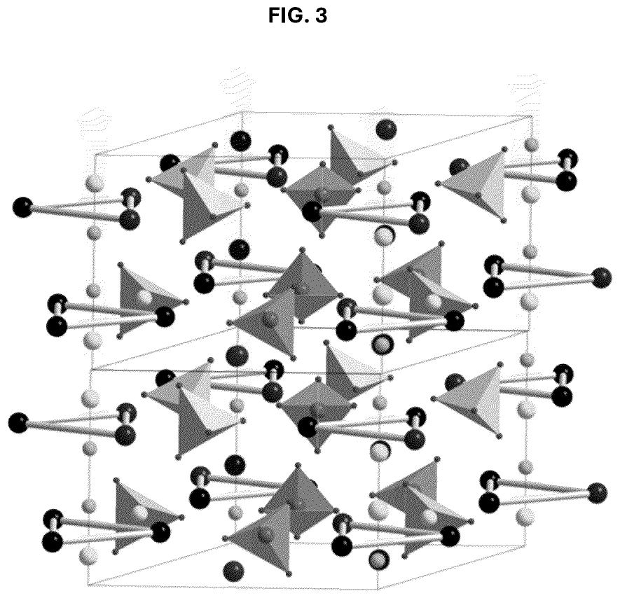

FIGS. 2 and 3 are schematic diagrams illustrating the structure of the ceramic compound according to the present invention. They represent the substitution of Pb with A (Cu, Sn, Ag, or combinations thereof), the substitution of phosphorus in phosphate with sulfur, and the substitution of oxygen in phosphate with sulfur. Additionally, these figures show the filling of the oxygen position in the central part, appearing as a 1-Dimension channel, with sulfur or electrons. FIG. 2 displays the structure and unit cell of the ceramic compound viewed from the c-axis, orthogonal to the a-b plane in a Cartesian coordinate system representing space. FIG. 3 illustrates the unit cell of FIG. 2 along the c-axis perpendicular to the a-b plane. The solid-line box indicates the unit structure of the ceramic compound of the present invention as an Apatite structure, and the arrow indicates the 1-Dimension channel.

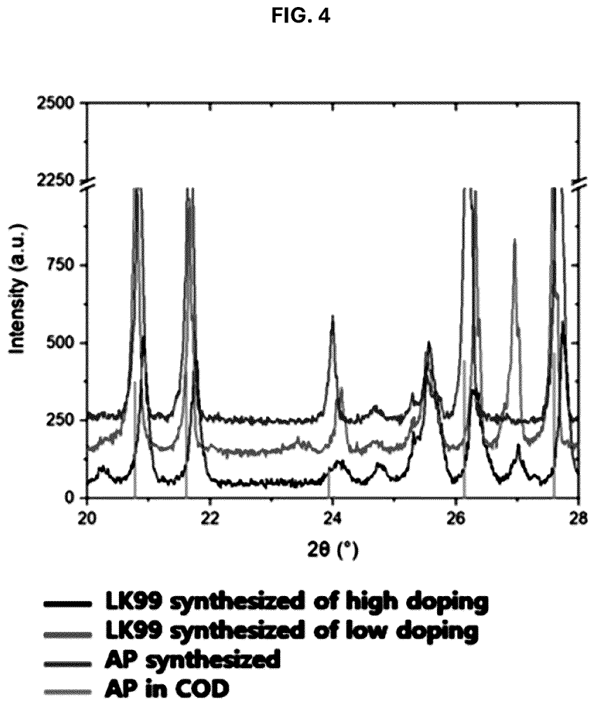

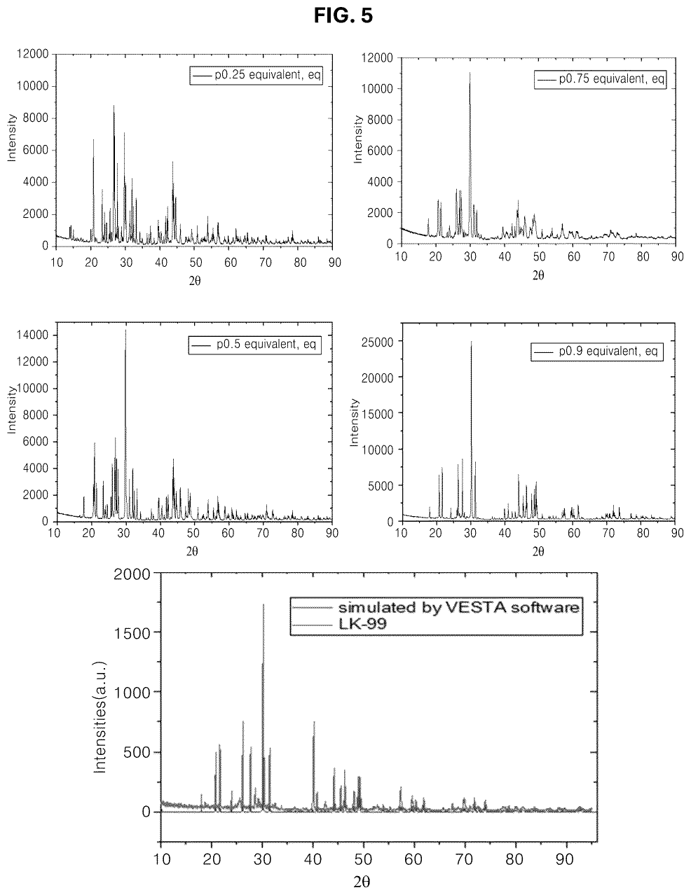

FIG. 4 shows the contraction that occurs due to volume reduction and stress generation when copper ions replace lead in the Lead-Apatite structure (Pb₁₀(PO₄)₆O), based on p-XRD calculations.

In Chemical Formula 1, a polyhedral structure is formed by six Pb(1) and channel oxygen (O), which constitutes the 1-Dimension channel. Upon closer inspection, the Pb(1) position shows that when Pb(1) is substituted with A (Cu, Sn, Ag, or combinations thereof), the arrangement remains relatively planar, with three Pb or A (Cu, Sn, Ag, or combinations thereof) layered in a triangular shape above or below. These triangles are not overlapping but staggered, and the position of the phosphate ((PO₄)₆) is arranged adjacent to each Pb(1) or A (Cu, Sn, Ag, or combinations thereof) metal.

This polyhedral structure, for example, with Pb, is denoted as asymmetric polyhedron 6Pb(1)-O(1). It extends vertically within the unit cell, generating electron density in a 1-Dimensional manner throughout the entire solid structure. This forms a cylindrical-like column structure surrounded by phosphate ions, sulfate ions, or thiophosphate ions, with their oxygen or sulfur atoms.

In more detail, six Pb(1) atoms form two layers, with three Pb(1) atoms in each layer, centered around four positions where channel oxygen (O(1)) can be located. When unit cells are continuous, the channel oxygen positions (O(1)) include a total of four sites where oxygen (O), sulfur (S), or electride (e-) can be placed according to the oxidation state of surrounding phosphate (PO₄), sulfate ions, or thiophosphate ions. When the 6Pb(1)-O(1) layers connect along the c-axis, a cylindrical column structure forms. This structure is surrounded by a 3D network made up of Pb(2)-O—P, Pb(2)-O—S, or Pb(2)-S—P.

In summary, LK-99 according to the present invention has a three-dimensional network structure overall. This network is surrounded by insulating tetrahedral phosphate ions (PO₄³⁻), sulfate ions (SO₄²⁻), and thiophosphate ions (PO₃S²⁻, PO₂S₂²⁻, POS₃²⁻, PS₄²⁻). Inside, the asymmetric polyhedra 6Pb(1)-O(1) are arranged, with two triangles (3Pb(1)) staggered vertically. A (Cu, Sn, Ag, or combinations thereof) can occupy the Pb(1) and Pb(2) positions within the crystal structure. Instead of replacing the polyhedral-forming A(Pb(1)), they may occupy the four Pb(2) atoms arranged on the outer shell of the polygonal or cylindrical column structure, contributing to condensation. When forming the internal column structure, they contribute to the distortion of the 1-Dimension Channel structure.

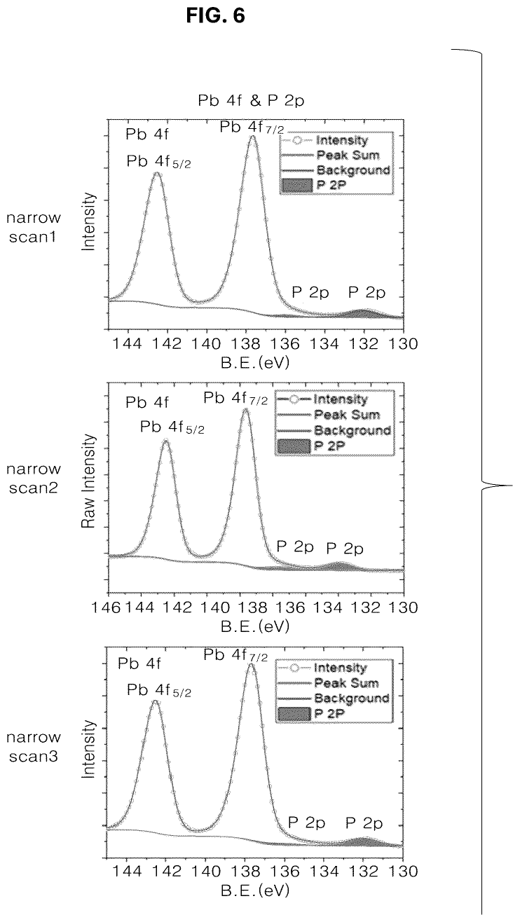

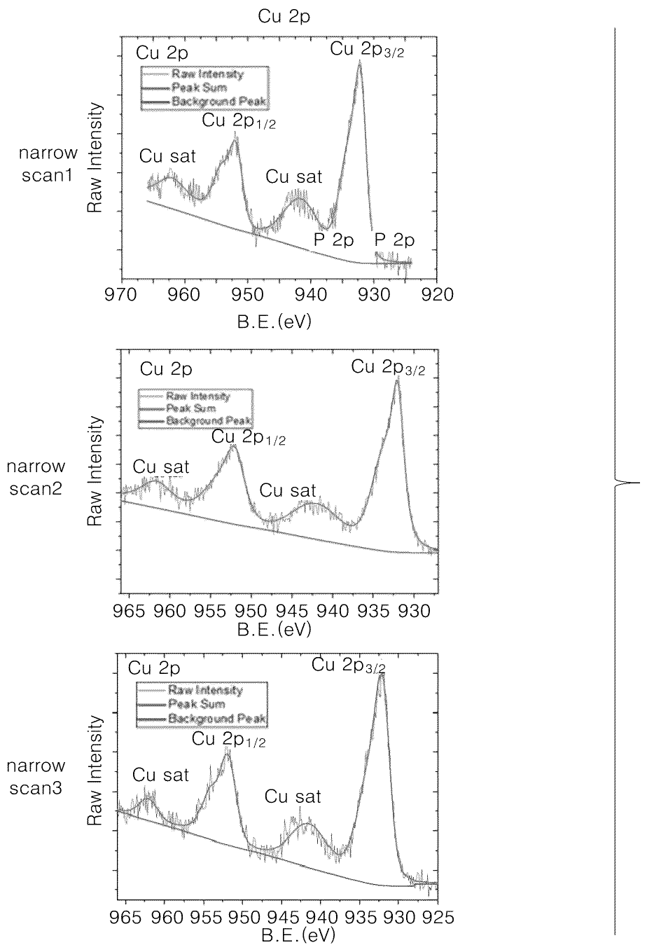

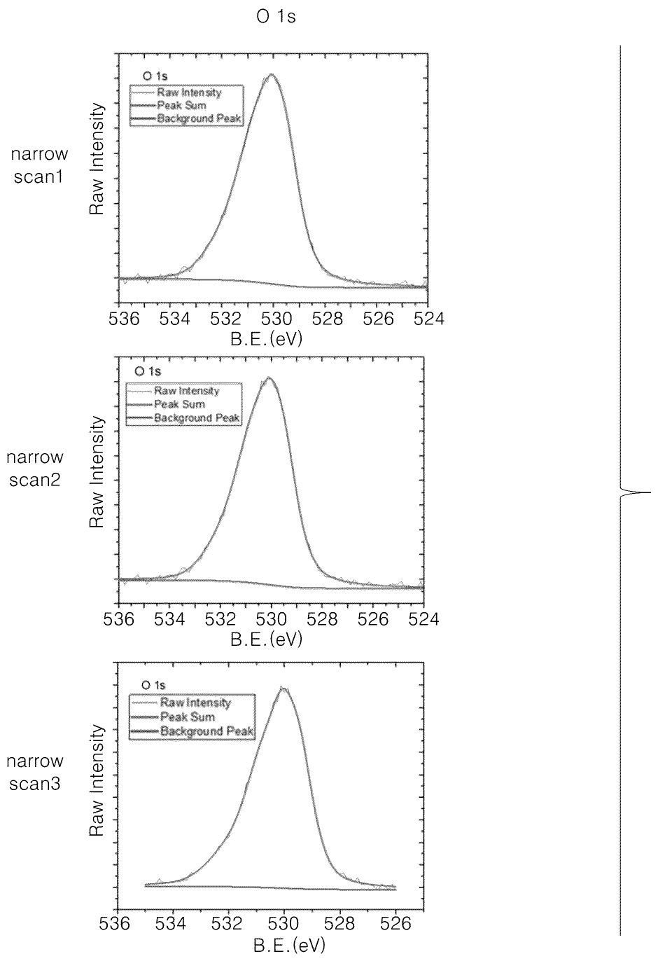

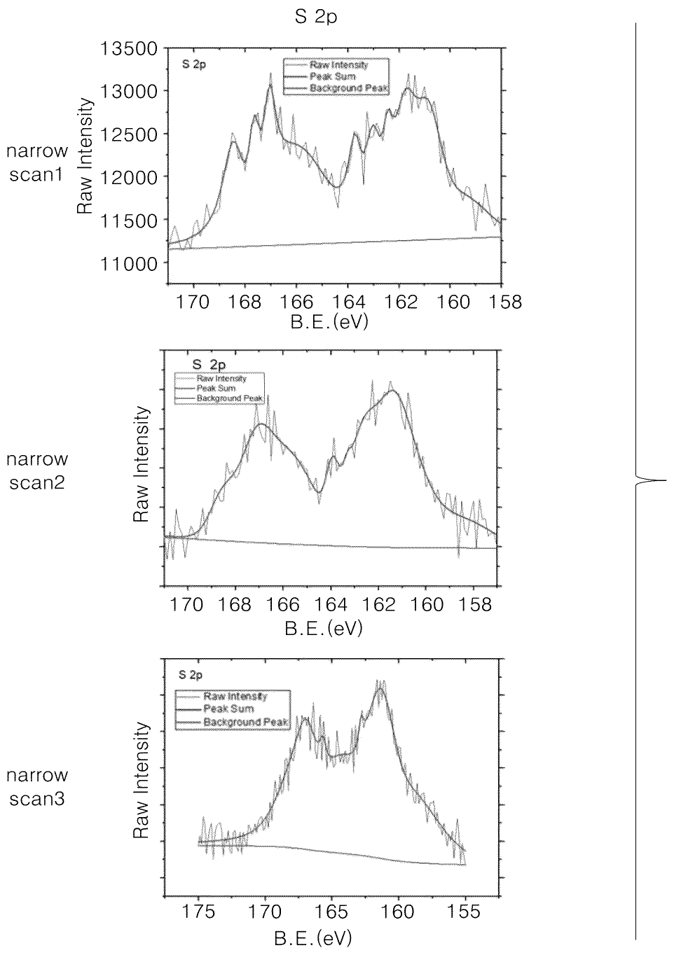

The substitution of copper ions in LK-99 results in a 0.48% volume reduction due to the smaller size of copper ions (Cu²⁺, 87 pm) compared to lead ions (Pb²⁺, 133 pm), and the stress generated by this volume reduction could ultimately influence superconductivity manifestation. The ratio of copper was determined based on the atomic % data from XPS, which is consistent with the results shown in FIG. 6.

Each atomic % in XPS is calculated by dividing the total number of electrons occupying the measured orbitals of each atom, after summing the areas of the binding energy peaks of the respective atom, by the relative sensitivity of the XPS measurement for that atom. By calculating the relative quantities of Pb and Cu, the ratio of copper can be determined. Based on XPS measurements, when the value of Pb is set to 10, the value of Cu can be calculated to be approximately 3.47.

Furthermore, the ceramic compound according to the present invention exhibits increased strength and hardness due to the arrangement changes caused by the presence of smaller ions (A(Cu²⁺, Ag²⁺, Sn²⁺)) at each position of Pb. This is because the substituted ions A(Cu²⁺, Ag²⁺, Sn²⁺) are smaller in size and volume compared to Pb²⁺, resulting in overall volume contraction.

In LK-99 of the present invention, the 1-Dimension channel column structure of 6Pb(1)-O(1) area is distorted, and the external insulating tetrahedral network structure condenses due to the presence of smaller metal ions (A(Cu²⁺, Ag²⁺, Sn²⁺)) at the Pb(2) positions. Consequently, the electron density along the 1-Dimension channel increases, leading to an increase in electron-electron interactions, which can be observed through current-voltage measurement experiments indicating the conductivity or superconductivity along this channel.

### Example 1—Synthesis of LK-99

The reaction materials PbO, 6Pb(SO)₄, Cu, and P powders were prepared in molar ratios of (10-x)/3:2/3(10-x):x:[(8/3(10-x)-y], uniformly mixed, and placed in a reaction vessel (quartz or copper tube). After vacuum sealing, the mixture was first heated to 770° C. for 12 hours to complete the reaction. The resulting ingot (where SO₂(s) is removed by evaporation) in the reaction vessel was powdered, and then subjected to a secondary heating at 550° C. for 5 hours under vacuum to vaporize sulfur (S₂(s)), removing it through evacuation according to the molar ratio

$$\frac{\text{?} - \text{?}}{\text{?}} ,$$

$$\text{?} \text{indicates text missing or illegible when filed}$$

thereby producing LK-99. The confirmation of the Apatite structure in the manufactured material was verified through p-XRD in the following experiment.

### Experimental Example 1—P-XRD Experiment of LK-99

The manufactured LK-99 was measured using XRD equipment (Rigaku, Japan SmartLab), and the results are shown in FIG. 6.

Experimental Example 2—XPS Experiment for Component Analysis of LK-99 The manufactured LK-99 was measured using XPS equipment, and the results are shown in FIG. 6.

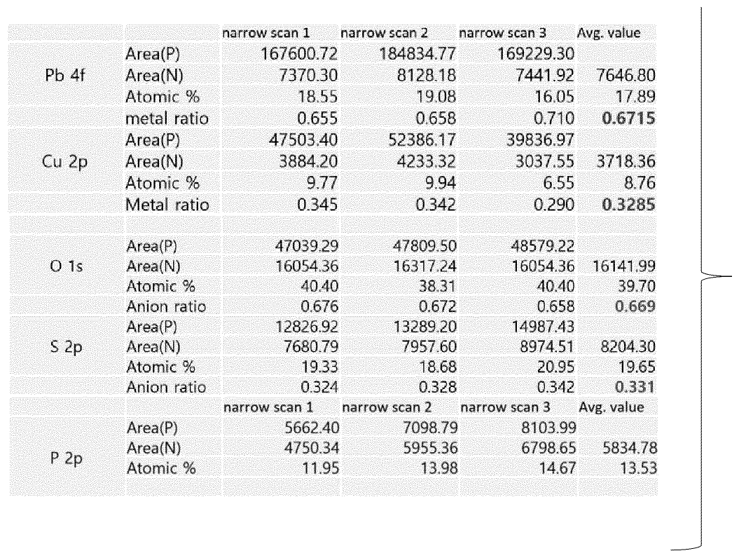

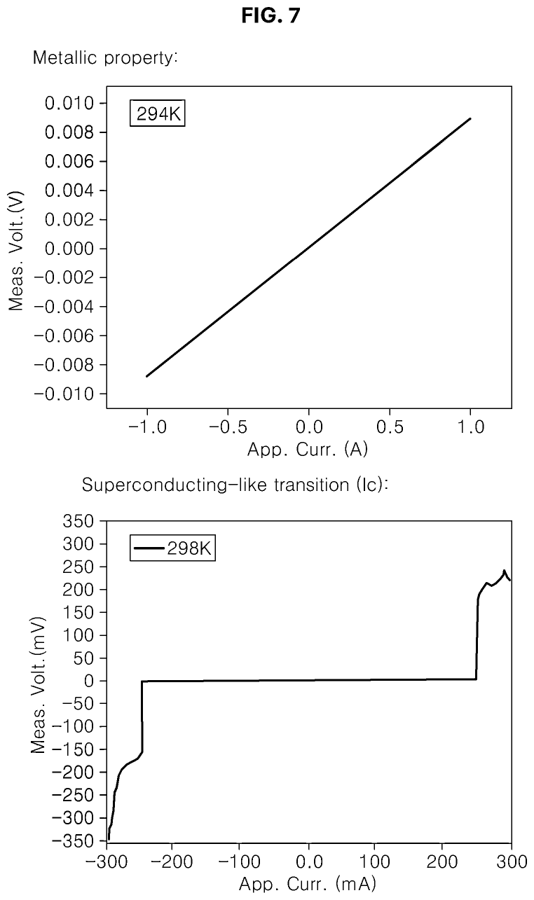

Referring to FIG. 7, it can be observed that the ceramic compound according to the present invention matches the chemical formula 1.

### Experimental Example 3—Current-Voltage Measurement of LK-99

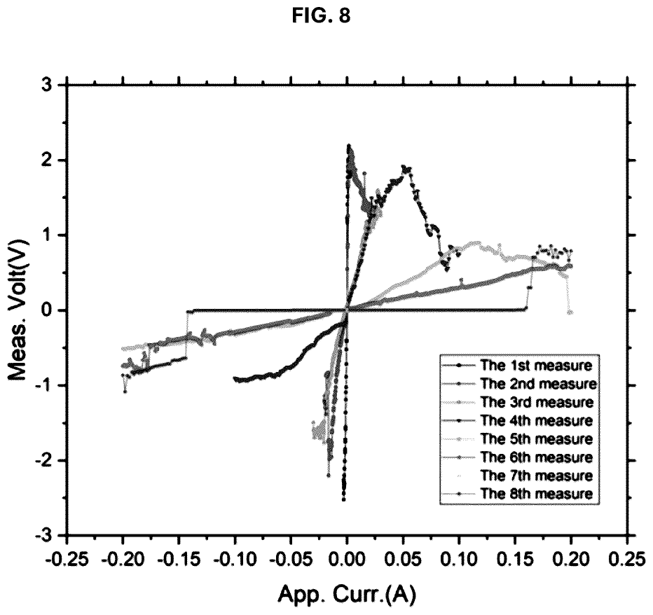

The manufactured LK-99 was processed into a cuboid bulk state using a ceramic cutter, and current-voltage measurements were conducted using a 4-terminal method (Keithley 228A, Keithley 182). The results of the measurements are presented in FIG. 8, which confirms the presence of metallic conductivity and characteristics such as critical current.

The LK-99 according to the present invention has various potential applications such as magnets, motors, cables, maglev trains, power cables, quantum computer qubits, THZ antennas, and more.

1. A method for producing a conductive or superconductive ceramic compound, characterized by mixing in a molar ratio according to chemical formula 1, heating and reacting the mixture under vacuum, then out gassing and powderizing the reaction product, and conducting secondary heating for vaporization under vacuum:
Pb10-xAx(B(O1-yCy)4)6Dz <Chemical Formula 1>
A: Cu, Ag, Sn, or combinations thereof,
B: P, S, or combinations thereof
C: S or O
D: S, O, e-, or combinations thereof
(x ranges from 0.1 to 7.0, y ranges from 0.001 to 10.0, z ranges from 1 to 4).

2. The method of claim 1, wherein the primary annealing ranges from 500° C. to 2000° C.

3. The method of claim 1, wherein the molar ratios are (10-x)/3:2/3(10-x):x:[(8/3(10-x)-y], according to reaction formula 1:
$$\underline{\frac{( 10 - x )}{3} PbO ( s ) + \frac{2 ( 10 - x )}{3} Pb {( SO )}_{\text{?}} ( s ) + xCu ( s ) + [ \frac{( \text{?} - \text{?} )}{3} - y ] P ( s ) \to } \qquad < Reaction Formula 1 >$$
$$\underline{{Pb}_{10 - x} {{Cu}_{x} [ ( {P ( {O}_{\text{?}} {S}_{\text{?}} )}_{4} ]}_{( 6 - y )} {{( {SO}_{4} )}_{y} [ {O}_{( 1 - \text{?} )} {S}_{} ]}_{z} + {SO}_{2} ( g ) + \frac{\text{?}}{\text{?}} {S}_{g} ( s )}$$
$$\underline{or}$$
$$\underline{{Pb}_{10 - x} {{Cu}_{x} [ ( {P ( {O}_{\text{?}} {S}_{\text{?}} )}_{4} ]}_{( 6 - y )} {{( {SO}_{4} )}_{y} [ {O}_{( 1 - \text{?} )} : {2}_{} ]}_{z} + {SO}_{\text{?}} ( g ) + \frac{\text{?}}{\text{?}} {S}_{\text{?}} ( s )}$$
$$\text{?} \text{indicates text missing or illegible when filed}$$

4. The method of claim 1, wherein the out gassing involves removal of gas containing sulfate.

5. The method of claim 1, wherein the vaporization involves vaporizing sulfur.

6. The method of claim 1, wherein the secondary heating ranges from 300° C. to 1200° C.

7. A conductive or superconductive ceramic compound produced by a method of any one of claims 1 to 6.

8. The ceramic compound of claim 7, wherein the ceramic compound exhibits diamagnetic behavior with temperature variations.

9. The ceramic compound of claim 7, wherein the ceramic compound exhibits diamagnetic or ferromagnetic behavior with changes in magnetic field.

10. The ceramic compound of claim 7, wherein the ceramic compound exhibits current-voltage characteristics with temperature variations described by V=I×R (V: voltage, I: current, R: resistance) or V≠I×R.

11. The ceramic compound of claim 7, wherein the ceramic compound exhibits current-voltage characteristics with changes in magnetic field described by V=I×R or V≠I×R.

12. The ceramic compound of claim 7, wherein the ceramic compound exhibits resistance-temperature characteristics following the law of Ohm's law beyond the transition temperature.

13. The ceramic compound of claim 7, wherein the ceramic compound exhibits resistance-current characteristics following the law of Ohm's law beyond the critical current.

14. The ceramic compound of claim 7, wherein the ceramic compound forms a cylindrical or similar pillar structure surrounding by phosphorus ions, sulfate ions, or thiophosphate ions in a continuous manner both upwards and downwards within a unit cell labeled as asymmetric polyhedron 6Pb(1)-O.

15. A superconductive ceramic compound characterized by a distribution structure of electrons in 1-Dimension to exhibit superconductivity or high conductivity under room temperature and atmospheric pressure.

16. The ceramic compound of claim 15, wherein the ceramic compound is a material with an Apatite structure in which the distribution structure of electrons is 1-Dimension to exhibit superconductivity or high conductivity under room temperature and atmospheric pressure.

17. The ceramic compound of claim 16, wherein the conductive or superconductive ceramic compound has a composition ratio according to Chemical Formula 1:
Pb₁₀₋ₓAₓ(B(O_{1-y}C_{y})₄)₆D_{z} <Chemical Formula 1>
A: Cu, Ag, Sn, or combinations thereof,
B: P, S, or combinations thereof
C: S or O
D: S, O, e-, or combinations thereof
(x ranges from 0.1 to 7.0, y ranges from 0.001 to 10.0, z ranges from 1 to 4).

18. The ceramic compound of claim 15 to 17, wherein the alteration of the lattice structure of the ceramic compound occurs due to the substitution of A.

19. The ceramic compound of claim 15 to 17, wherein overall, it has a 3-dimensional network structure, surrounded by insulating tetrahedral ions (PO₄³⁻), (SO₄²⁻), thiophosphate ions (PO₃S²⁻, PO₂S₂²⁻, POS₃²⁻, PS₄²⁻).
